(19) United States
(12) Patent Application Publication
(10) Pub. No.: US 2025/0212455 A1
(43) Pub. Date: Jun. 26, 2025

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Cheng-Wei LIU, Hsinchu City (TW); Ji-Yin TSAI, Hsinchu County (TW); Ming-Hua YU, Hsinchu City (TW); Chii-Horng LI, Hsinchu County (TW)

(73) Assignee: TAIWAN SEMICONDUCTOR MANUFACTURING COMPANY, LTD., Hsinchu (TW)

(21) Appl. No.: 18/393,283

(22) Filed: Dec. 21, 2023

(51) Int. Cl. H01L 29/786; H01L 27/088; H01L 29/08; H01L 29/423; H01L 29/66; H01L 29/775

(52) U.S. Cl. CPC H10D 30/6706; H10D 30/014; H10D 30/031; H10D 30/43; H10D 62/151; H10D 64/018; H10D 84/83; H10D 30/6735; H10D 30/6757

(57) ABSTRACT

A semiconductor device includes a substrate. Semiconductor layers are stacked one above another over the substrate. A gate structure wraps around each of the semiconductor layers. Epitaxial layers are over the substrate and in contact with opposite ends of a bottommost one of the semiconductor layers. Source/drain epitaxial structures are over and in contact with the epitaxial layers, respectively. Dielectric structures vertically between the epitaxial layers and the respective source/drain epitaxial structures, respectively.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 17 illustrate a method in various stages of forming a semiconductor device in accordance with some embodiments of the present disclosure.

FIG. 18 is an enlarged view of a semiconductor device in accordance with some embodiments of the present disclosure.

FIG. 19 is an enlarged view of a semiconductor device in accordance with some embodiments of the present disclosure.

FIG. 20 is an enlarged view of a semiconductor device in accordance with some embodiments of the present disclosure.

FIG. 21 is an enlarged view of a semiconductor device in accordance with some embodiments of the present disclosure.

FIG. 22 is a cross-section view of a semiconductor device in accordance with some embodiments of the present disclosure.

FIGS. 23 to 26 illustrate a method in various stages of forming a semiconductor device in accordance with some embodiments of the present disclosure.

FIG. 27 is a cross-section view of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

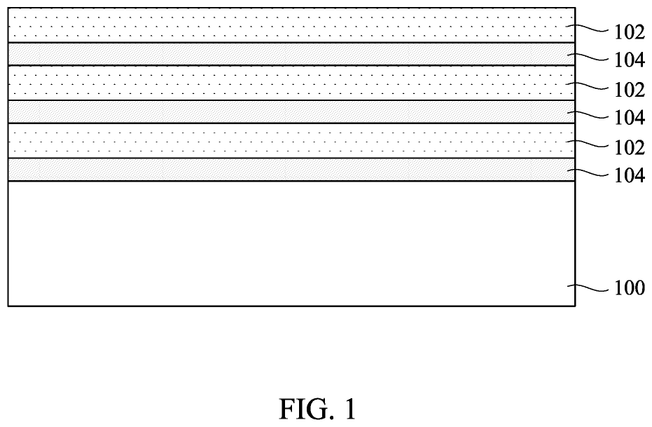

FIGS. 1 to 17 illustrate a method in various stages of forming a semiconductor device in accordance with some embodiments of the present disclosure. Although FIGS. 1 to 17 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 1. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A stack of alternating semiconductor layers 102 and semiconductor layers 104 is formed over the substrate 100. In some embodiments, the semiconductor layers 102 may be made of pure silicon layers that are free of germanium. The semiconductor layers 102 may also be substantially pure silicon layers, for example, with a germanium percentage lower than about 1 percent. The semiconductor layers 104 may be made of silicon germanium. For example, the germanium percentage (atomic percentage concentration) of the semiconductor layers 104 is in a range from about 20 percent and about 50 percent. In some embodiments, the semiconductor layers 102 and 104 may be deposited using suitable deposition process, such as selective epitaxial growth (SEG), chemical vapor deposition (CVD), molecular beam epitaxy (MBE), or other suitable process(es).

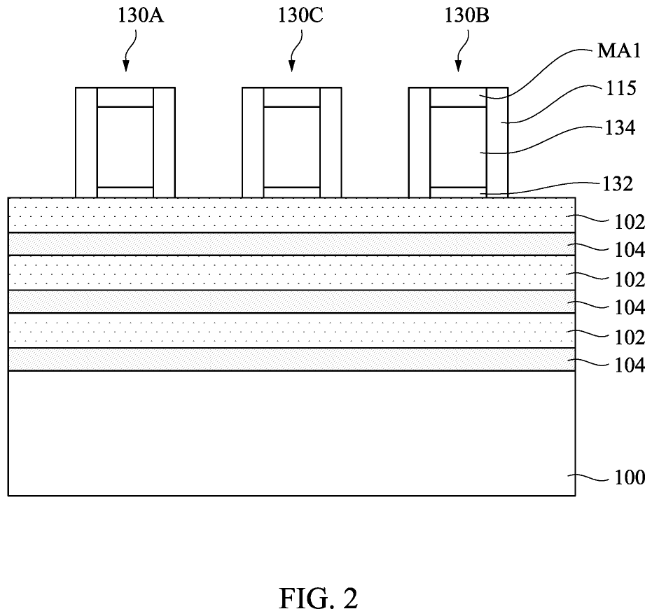

Reference is made to FIG. 2. Dummy gate structures 130A, 130B, and 130C are formed over the substrate 100 and crossing the stack of alternating semiconductor layers 102 and semiconductor layers 104, in which the dummy gate structure 130C is laterally between the dummy gate structures 130A and 130B. In some embodiments, each of the dummy gate structures 130A, 130B, and 130C includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation. In some embodiments, the patterned masks MA1 may include silicon oxide, silicon nitride, combinations thereof, or other suitable materials.

Gate spacers 115 are formed on opposite sidewalls of each of the dummy gate structures 130A, 130B, and 130C. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130A, 130B, and 130C. In some embodiments, the remaining vertical portions of the spacer layer on sidewalls of the dummy gate structures 130A, 130B, and 130C can be referred to as gate spacers 115. In some embodiments, the spacer layer may be deposited using techniques such CVD, ALD, or the like.

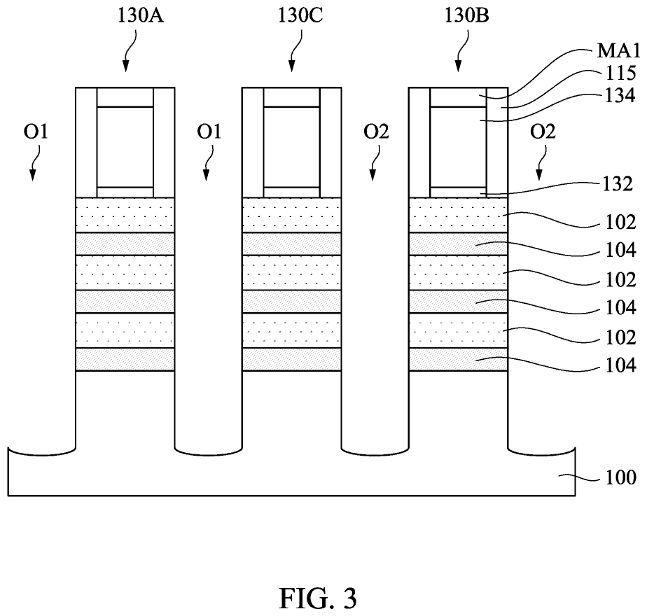

Reference is made to FIG. 3. The stack of alternating semiconductor layers 102 and semiconductor layers 104 and the substrate 100 are etched, by using the gate spacers 115 and the patterned masks MA1 (or the dummy gate structures 130A, 130B, and 130C) as etch mask, to form openings in the stack of alternating semiconductor layers 102 and semiconductor layers 104 and the substrate 100. In greater detail, the openings on opposite sides of the dummy gate structures 130A are referred to as source/drain openings O1, and the openings on opposite sides of the dummy gate structures 130B are referred to as source/drain openings O2. In some embodiments, the etching process is performed until bottommost ends of the source/drain openings O1 and O2 are lower than the bottommost semiconductor layer 104. The etching process may include dry etch, wet etch, or combinations thereof.

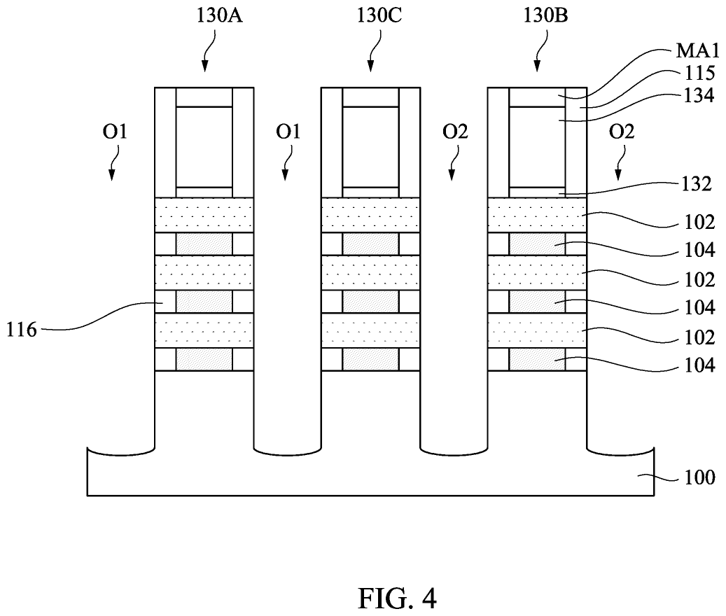

Reference is made to FIG. 4. The semiconductor layers 104 are laterally etched to form sidewall recesses. Then, inner spacers 116 are formed in the sidewall recesses on opposite ends of each of the semiconductor layers 104. In some embodiments, the inner spacers 116 may be formed by, for example, depositing an inner spacer layer blanket over the substrate 100 and filling the sidewall recesses on opposite sides of the semiconductor layers 104, and then performing an anisotropic etching to remove portions of the inner spacer layer outside the sidewall recesses, leaving the remaining portions of the inner spacer layer in the sidewall recesses as the inner spacers 116. The inner spacers 116 may be deposited by a conformal deposition process, such as CVD, ALD, or the like. The inner spacer layer may include a material such as SiN, SiOCN, SiCN, SiOC, although any suitable material, such as low-dielectric constant (low-k) materials having a k-value less than about 3.5, may be utilized.

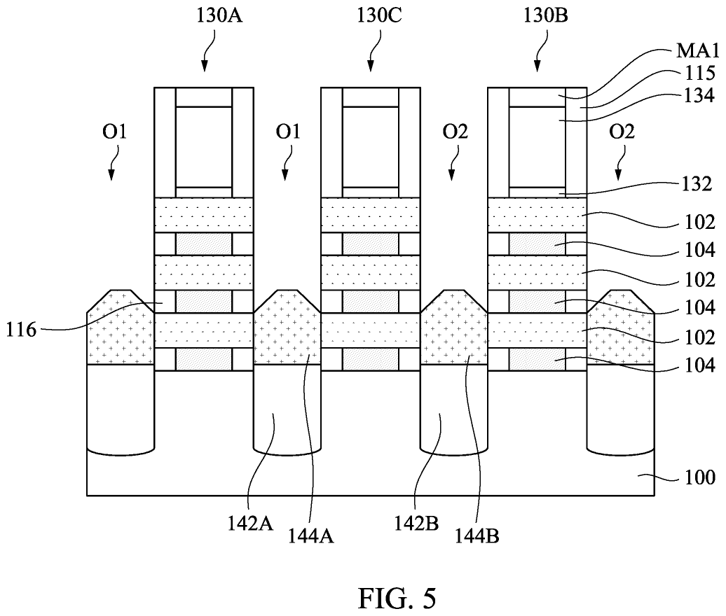

Reference is made to FIG. 5. Epitaxial layers 142A and 142B are formed at bottom portions of the source/drain openings O1 and O2, respectively. Afterwards, epitaxial layers 144A and 144B are formed over the epitaxial layers 142A and 142B, respectively. In greater detail, the epitaxial layers 142A and 142B are formed from bottom portions of the source/drain openings O1 and O2 until top surfaces of the epitaxial layers 142A and 142B are higher than top surface of the substrate 100 (or higher than bottom surface of the bottommost semiconductor layer 104). The epitaxial layers 144A and 144B are then formed over the epitaxial layers 142A and 142B until sidewalls of the bottommost semiconductor layer 102 are covered by the epitaxial layers 144A and 144B. In some embodiments, the epitaxial layers 142A/142B and the epitaxial layers 144A/144B are un-doped.

In some embodiments, the formation of the epitaxial layers 142A and 142B may include one or more deposition cycles, in which each deposition cycle may include a selective epitaxial growth (SEG) process and an etching process. In some embodiments, the SEG process may selectively grow a semiconductor material on exposed semiconductor surfaces, such as the exposed surfaces of the substrate 100 and the exposed surfaces of the semiconductor layers 102. However, because the exposed areas of the substrate 100 are greater than the exposed area of each of the semiconductor layers 102, the semiconductor material may include higher growing rate on the exposed areas of the substrate 100 than on the exposed area of each of the semiconductor layers 102. That is, a greater amount of the semiconductor material will be grown on the exposed areas of the substrate 100 than on the exposed area of each of the semiconductor layers 102. As a result, the etching process in each deposition cycle of the epitaxial layers 142A and 142B may remove portions of the semiconductor material formed on the exposed area of each of the semiconductor layers 102, while portions of the semiconductor material may remain over the substrate 100 after the etching process. Accordingly, performing at least one deposition cycle may allow a bottom-up deposition for the epitaxial layers 142A and 142B. That is, the 142A and 142B may be formed from the bottoms of the source/drain openings O1 and O2 via a bottom-up manner.

Similarly, the formation of the epitaxial layers 144A and 144B may also include one or more deposition cycles, in which each deposition cycle may include a selective epitaxial growth (SEG) process and an etching process. Because the epitaxial layers 142A and 142B include larger exposed area than the semiconductor layers 102, the epitaxial layers 144A and 144B can also be formed from the bottoms of the source/drain openings O1 and O2 via a bottom-up manner.

The epitaxial layers 142A and 142B may include silicon (Si) or silicon germanium (Si₁₋ₓGeₓ). In some embodiments, x is in a range from about 0 to about 0.4. The epitaxial layers 144A and 144B may include silicon germanium (Si_{1-y}Ge_{y}). In some embodiments, y is in a range from about 0 to about 0.4. In some embodiments, x is less than y.

In some embodiments where the epitaxial layers 142A/142B and the epitaxial layers 144A/144B are made of silicon germanium (SiGe). The deposition of the epitaxial layers 142A/142B and the epitaxial layers 144A/144B may include supplying silicon-containing precursor and germanium silicon-containing precursor. Exemplary silicon-containing precursor includes SiH₄, Si₂H₆, H₂SiCl₂, SiₓH₂ₓ₊₂ high order silane, or the like. Exemplary germanium silicon-containing precursor includes GeH₄, or the like. During the deposition of the epitaxial layers 142A/142B and the epitaxial layers 144A/144B, hydrochloric acid (HCl) may also be supplied as a reaction gas (or etching gas) for conducting the etching process as described above in the deposition cycle. In some embodiments, the deposition temperature is in a range from about 500° C. to about 800° C. (e.g., 600° C. to 700° C. in some embodiments). The pressure is in a range from about 10 torr to about 130 torr (e.g., 50 torr in some embodiments).

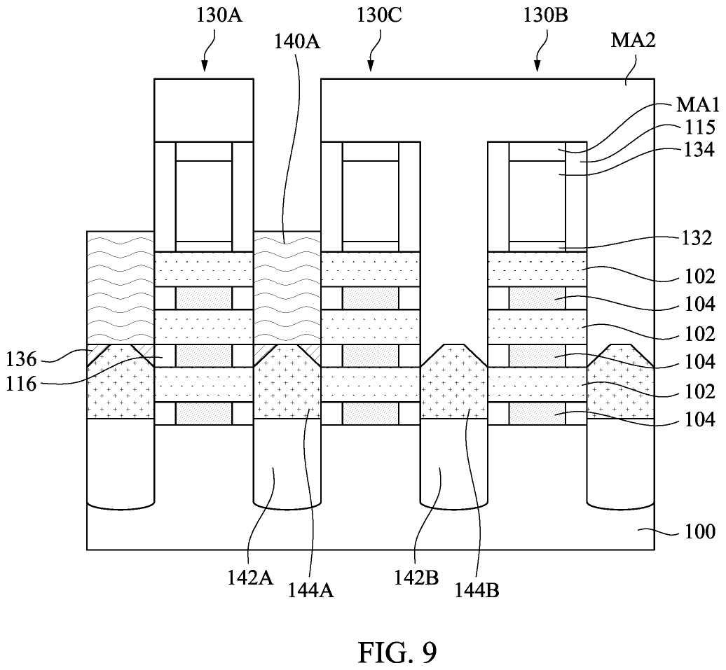

In some embodiments, the flow rate of hydrochloric acid (HCl) for depositing the epitaxial layers 142A/142B may be different from the flow rate of hydrochloric acid (HCl) for depositing the epitaxial layers 144A/144B. This will result in that the epitaxial layers 142A/142B may include different top surface profile than the epitaxial layers 144A/144B. For example, the flow rate of hydrochloric acid (HCl) for depositing the epitaxial layers 144A/144B is greater than the flow rate of hydrochloric acid (HCl) for depositing the epitaxial layers 142A/142B. As a result, the epitaxial layers 142A/142B may include substantially flat top surface profile, while the epitaxial layers 144A/144B may include a non-flat top surface profile, such as a trapezoidal top surface profile. Stated another way, top surfaces of the epitaxial layers 142A/142B may be flatter than top surfaces of the epitaxial layers 144A/144B. With respect to the epitaxial layers 144A/144B, the trapezoidal top surface profile may include two inclined surfaces and a horizontal surface connecting the inclined surfaces. In some embodiments, the non-flat top surface profile may be beneficial to avoid edge defects to maintaining crystal strain of the following formed source/drain structure (e.g., the source/drain epitaxial structures 140A in FIG. 9).

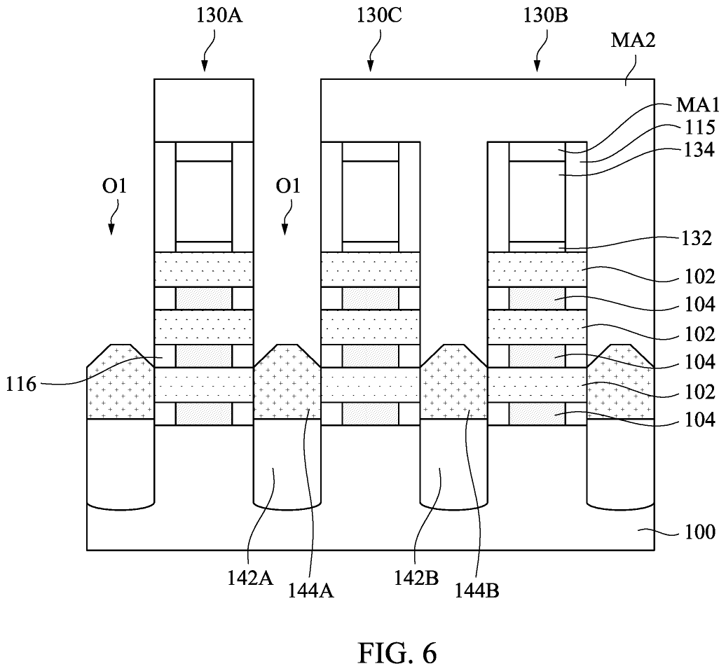

Reference is made to FIG. 6. A patterned mask MA2 is formed over the substrate 100. In greater detail, the patterned mask MA2 covers the dummy gate structures 130A, 130B, and 130C, and fills the source/drain openings O2 to cover the epitaxial layers 144B. On the other hand, the patterned mask MA2 may include openings exposing the source/drain openings O1, such that the epitaxial layers 144A in the source/drain openings O1 are exposed through the patterned mask MA2. In some embodiments, the patterned mask MA2 may be a hard mask, and may be made of metal oxide or other suitable materials.

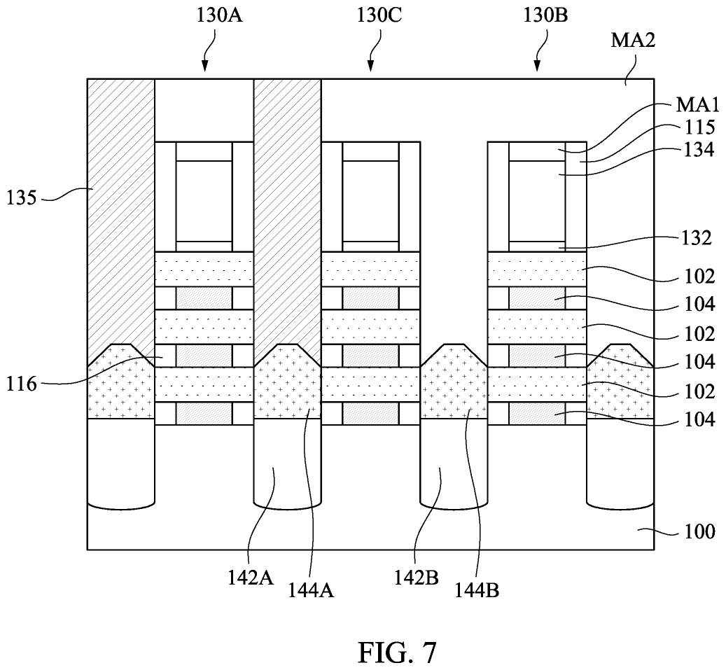

Reference is made to FIG. 7. A dielectric layer 135 is deposited over the substrate 100 and filling the source/drain openings O1. The dielectric layer 135 may be formed by, for example, depositing a dielectric material over the substrate 100 and overfilling the source/drain openings O1, and then performing a planarization process, such as CMP, to remove excess dielectric material until top surface of the patterned mask MA2 is exposed. In some embodiments, the dielectric layer 135 may include silicon (Si), carbon (C), oxygen (O), and/or nitrogen (N). For example, the dielectric layer 135 may include silicon carbide (SiC), silicon oxide (SiO₂), silicon nitride (SIN), silicon oxycarbide (SiOC), silicon carbon nitride (SiCN), silicon oxynitride (SiON), silicon oxycarbonitride (SiOCN). The dielectric layer 135 may be deposited using suitable deposition process, such as chemical CVD, ALD, or the like.

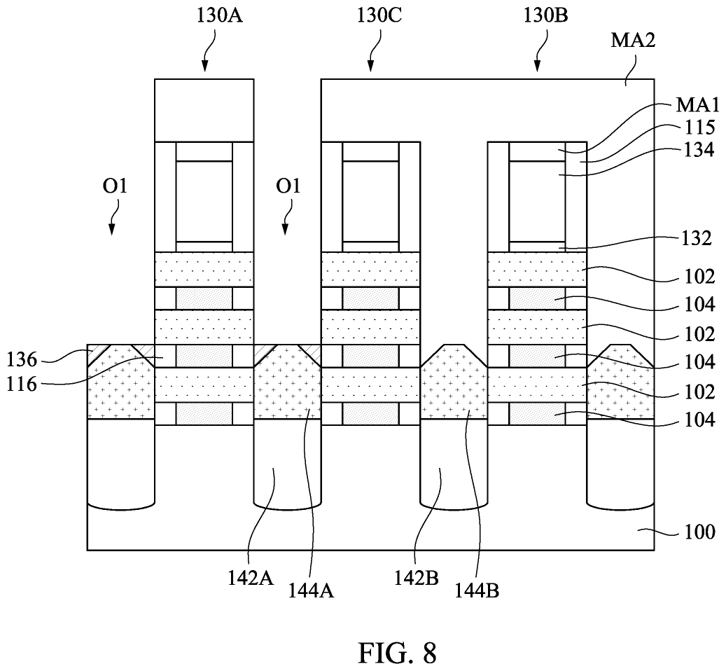

Reference is made to FIG. 8. An etching back process is performed on the dielectric layer 135, so as to lower top surface of the dielectric layer 135 until top surfaces of the epitaxial layers 144A are exposed. In greater detail, the horizontal surfaces of the epitaxial layers 144A may be exposed as a result of the etching back process. On the other hand, the portions of the dielectric layer 135 may remain in contact with the inclined surfaces of the epitaxial layers 144A after the etching back process is complete. That is, the remaining portions of the dielectric layer 135 are on opposite sides of each of the epitaxial layers 144A after the etching back process is complete. The remaining portions of the dielectric layer 135 are referred to as dielectric structures 136 in the following discussion. In some embodiments, the etching back process may include wet etch, dry etch, or combinations thereof.

Reference is made to FIG. 9. Source/drain epitaxial structures 140A are formed on opposite ends of each of the semiconductor layers 102 through the source/drain openings O1. The source/drain epitaxial structures 140A may be formed by suitable deposition process, such as a selective epitaxial growth (SEG) process. In some embodiments, the SEG process may selectively grow a semiconductor material on exposed semiconductor surfaces, such as the exposed surfaces of the epitaxial layers 144A and the exposed surfaces of the semiconductor layers 102. In some embodiments, an implantation process may be performed to the source/drain epitaxial structures 140A. For example, the source/drain epitaxial structures 140A may be doped with p-type dopants, such as boron (B), gallium (Ga), indium (In), aluminium (Al), or the like. In some embodiments, the source/drain epitaxial structures 140A may be doped with n-type dopants, such as phosphorus (P), arsenic (As), or antimony (Sb), or the like.

Because the dielectric layer 135 is etched back to expose the epitaxial layers 144A, the exposed epitaxial layers 144A may provide additional nucleation sites for the source/drain epitaxial structures 140A, and thus the source/drain epitaxial structures 140A can be formed having a void-free structure. If the epitaxial layers 144A are covered by the dielectric layer 135, void may be formed between the source/drain epitaxial structures 140A and the dielectric layer 135. Moreover, the remaining dielectric structures 136 can also provide electrical isolation between the source/drain epitaxial structures 140A and the bottommost semiconductor layer 102, and will prevent current leakage from the source/drain epitaxial structures 140A to the bottommost semiconductor layer 102. With such configuration, the device performance may be improved.

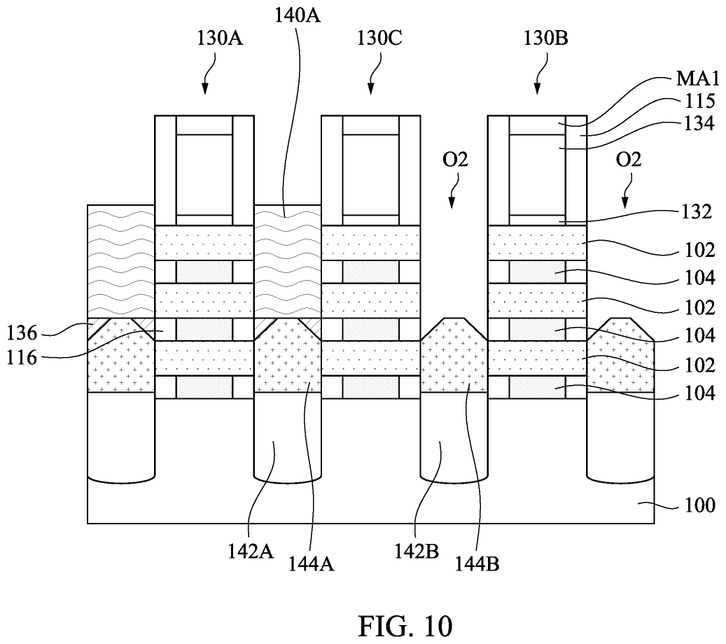

Reference is made to FIG. 10. After the source/drain structures 140A are formed, the patterned mask MA2 is removed, so as to reveal the source/drain openings O2. In some embodiments, the patterned mask MA2 may be removed using suitable etching process, such as dry etch or wet etch.

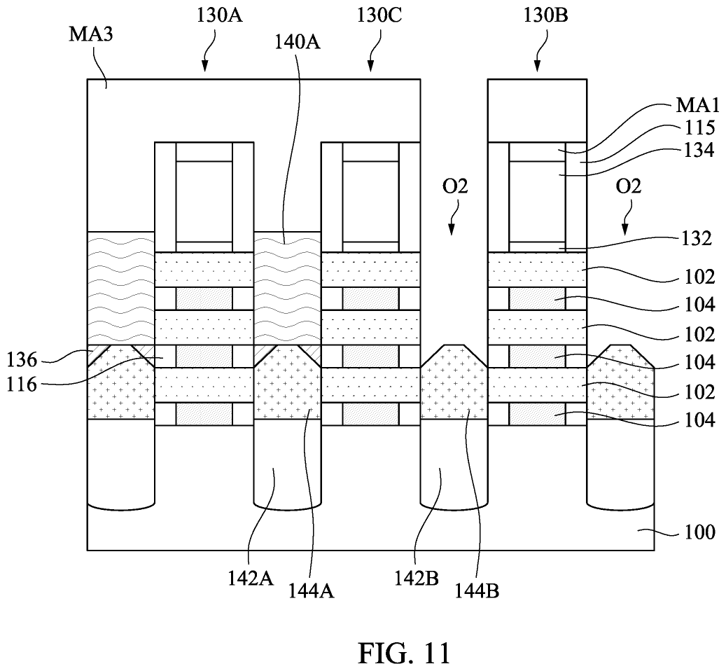

Reference is made to FIG. 11. A patterned mask MA3 is formed over the substrate 100. In greater detail, the patterned mask MA3 covers the dummy gate structures 130A, 130B, and 130C, and covers the source/drain epitaxial structures 140A. On the other hand, the patterned mask MA3 may include openings exposing the source/drain openings O2, such that the epitaxial layers 144B in the source/drain openings O2 are exposed through the patterned mask MA3. In some embodiments, the patterned mask MA3 may be a hard mask, and may be made of metal oxide, or other suitable materials.

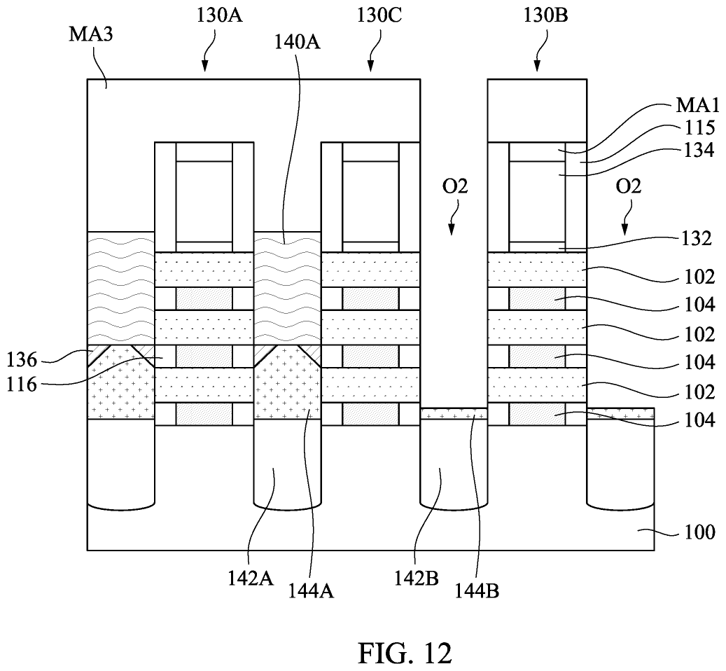

Reference is made to FIG. 12. An etching back process is performed to the epitaxial layers 144B, so as to lower top surfaces of the epitaxial layers 144B to a position lower than the bottommost semiconductor layer 102. In greater detail, the epitaxial layers 144B are etched back to expose sidewalls of the bottommost semiconductor layer 102 under the dummy gate structure 130B. In some embodiments, each of the etched epitaxial layers 144B may include substantially flat top surface profile. Top surfaces of the etched epitaxial layers 144B may be lower than top surfaces of the epitaxial layers 144A, and may be flatter than top surfaces of the epitaxial layers 144A. In some embodiments, the etching back process may include wet etch, dry etch, or combinations thereof.

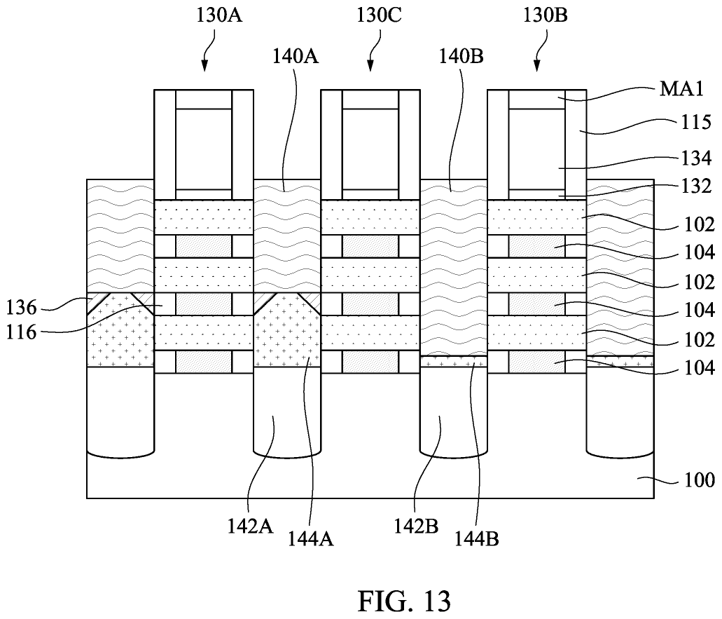

Reference is made to FIG. 13. Source/drain epitaxial structures 140B are formed on opposite ends of each of the semiconductor layers 102 through the source/drain openings O2. Because the epitaxial layers 144B are etched back, the source/drain epitaxial structures 140B may be formed in contact with the bottommost semiconductor layer 102 under the dummy gate structure 130B. Accordingly, bottom surfaces of the source/drain epitaxial structures 140B may lower than bottom surfaces of the source/drain epitaxial structures 140A. The source/drain epitaxial structures 140B may be formed by suitable deposition process, such as a selective epitaxial growth (SEG) process. In some embodiments, the SEG process may selectively grow a semiconductor material on exposed semiconductor surfaces, such as the exposed surfaces of the epitaxial layers 144B and the exposed surfaces of the semiconductor layers 102. In some embodiments, an implantation process may be performed to the source/drain epitaxial structures 140B. For example, the source/drain epitaxial structures 140B may be doped with p-type dopants, such as boron (B), gallium (Ga), indium (In), aluminium (Al), or the like. In some embodiments, the source/drain epitaxial structures 140B may be doped with n-type dopants, such as phosphorus (P), arsenic (As), or antimony (Sb), or the like.

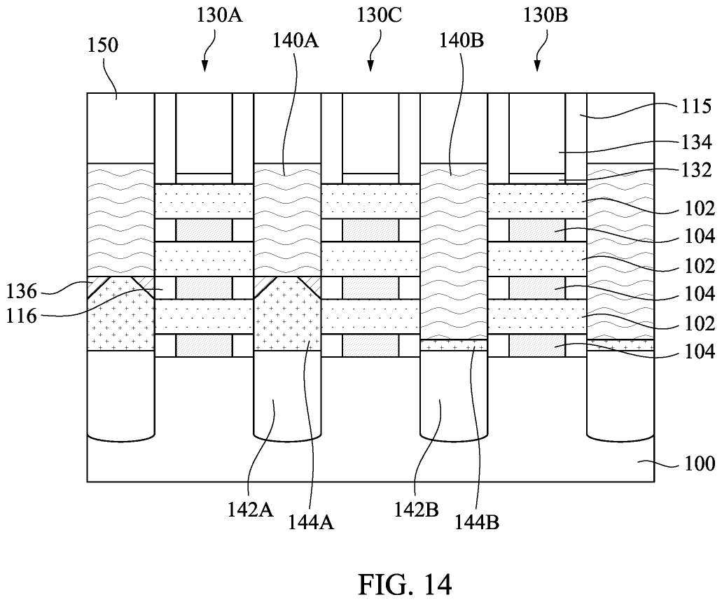

Reference is made to FIG. 14. An interlayer dielectric (ILD) layer 150 is formed over the substrate 100 and covering the source/drain epitaxial structures 140A and 140B. Then, a planarization process, such as CMP, is performed to remove excess materials of the ILD layer 150 until the dummy gate structures 130A, 130B, and 130C are exposed. In some embodiments, the patterned masks MA1 are removed during the planarization process. In some embodiments, a contact etch stop layer (CESL) (not shown) may be formed over the substrate 100 prior to forming the ILD layer 150.

In some embodiments, the CESL may be a dielectric layer including silicon nitride, silicon oxynitride or other suitable materials. In some embodiments, the ILD layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

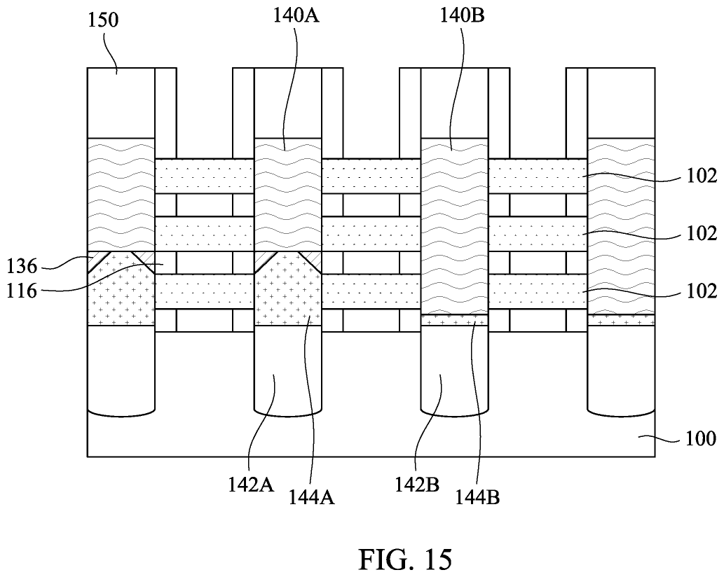

Reference is made to FIG. 15. The dummy gate structures 130A, 130B, and 130C are removed to form gate trenches between each pair of the gate spacers 115. Afterwards, the semiconductor layers 104 are removed, such that the semiconductor layers 102 are suspended over the substrate 100.

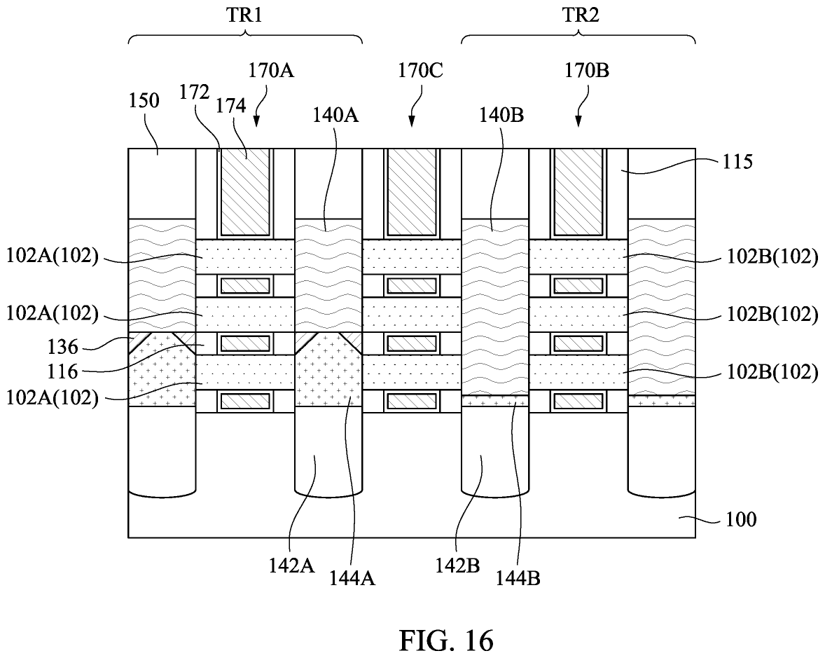

Reference is made to FIG. 16. Metal gate structures 170A, 170B, and 170C are formed in the gate trenches and wrapping around the respective semiconductor layers 102. Each of the metal gate structures 170A, 170B, and 170C may include a gate dielectric layer 172 and a gate electrode 174 over the gate dielectric layer 172. The metal gate structures 170A, 170B, and 170C may be formed by, for example, sequentially depositing gate dielectric material and gate electrode material in the gate trenches and wrapping around the respective semiconductor layers 102, and then performing a planarization process, such as CMP, to remove excess gate dielectric material and excess gate electrode material until the ILD layer 150 is exposed.

In some embodiments, the gate dielectric layer 172 may include an interfacial layer and a high-k dielectric layer over the interfacial layer. In some embodiments, the interfacial layer may be made of oxide, such as aluminum oxide (Al₂O₃), silicon oxide (SiO₂), or the like. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 174 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

After the metal gate structures 170A, 170B, and 170C are formed, a hybrid sheet structure is formed. The hybrid sheet structure includes a first transistor TR1 and a second transistor TR2. With respect to the first transistor TR1, the first transistor TR1 includes the semiconductor layers 102A, the source/drain epitaxial structures 140A in contact with opposite ends of each of the semiconductor layers 102A, and the metal gate structures 170A wraps around each of the semiconductor layers 102A. In particular, the bottommost semiconductor layer 102A is in contact with the epitaxial layers 144A, which are un-doped, and thus the no current or negligible current will flow through the bottommost semiconductor layer 102A. That is, the bottommost semiconductor layer 102A may be “disabled”, and may not serve as a channel layer of the first transistor TR1.

On the other hand, with respect to the second transistor TR2, the second transistor TR2 includes the semiconductor layers 102B, the source/drain epitaxial structures 140B in contact with opposite ends of each of the semiconductor layers 102B, and the metal gate structures 170B wraps around each of the semiconductor layers 102B. Different from the first transistor TR1, the source/drain epitaxial structures 140B are in contact with all of the semiconductor layers 102B, and thus the second transistor TR2 may include more active channel layers than the first transistor TR1.

It is noted that, the number of the semiconductor layers 102 are merely used to explain, the present disclosure is not limited thereto. In some embodiments, the total number of the semiconductor layers 102 may be N, where 2≤N≤6. In some embodiments, the number of the disabled semiconductor layers 102 may be n, where 1≤n≤N−1.

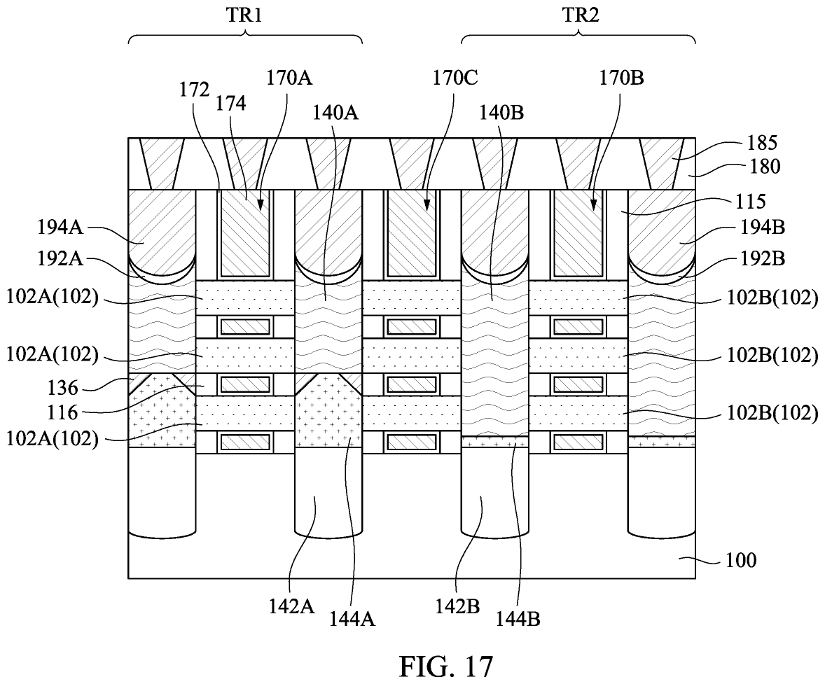

Reference is made to FIG. 17. The ILD layer 150 is removed by suitable process, such as etching process, so as to expose the underlying source/drain epitaxial structures 140A and 140B. Silicide layers 192A and 192B are formed on the exposed surfaces of the source/drain epitaxial structures 140A and 140B, respectively. Afterwards, source/drain contacts 194A and 194B are formed over the silicide layers 192A and 192B, respectively, such that the source/drain contacts 194A and 194B are electrically connected to the respective source/drain epitaxial structures 140A and 140B. Afterwards, interlayer dielectric (ILD) layer 180 is formed over the substrate 100 and covering the metal gate structures 170A, 170B, and 170C and the source/drain contacts 194A and 194B. Conductive vias 185 are formed in the ILD layer 180 and in contact with the respective metal gate structures 170A, 170B, and 170C and the respective source/drain contacts 194A and 194B. In some embodiments, the conductive vias 185 in contact with the metal gate structures 170A, 170B, and 170C can be referred to as gate vias, and the conductive vias 185 in contact with the source/drain contacts 194A and 194B can be referred to as source/drain vias.

In some embodiments, the silicide layers 192A and 192B may include CoSi₂, TiSi₂, WSi₂, NiSi₂, MoSi₂, TaSi₂, PtSi, or the like. In some embodiments, each of the source/drain contacts 194A and 194B may include a diffusion barrier and a contact plug over the diffusion barrier. In some embodiments, the diffusion barrier may include titanium (Ti), titanium nitride (TiN), tantalum (Ta), tantalum nitride (TaN), or another suitable material. The contact plug may include a conductive material, such tungsten (W), copper (Cu), aluminum (Al), ruthenium (Ru), cobalt (Co), molybdenum (Mo), nickel (Ni), or other suitable conductive material. In some embodiments, the ILD layer 180 may include similar material as the ILD layer 150. The conductive vias 185 may include a conductive material, such tungsten (W), copper (Cu), aluminum (Al), ruthenium (Ru), cobalt (Co), molybdenum (Mo), nickel (Ni), or other suitable conductive material.

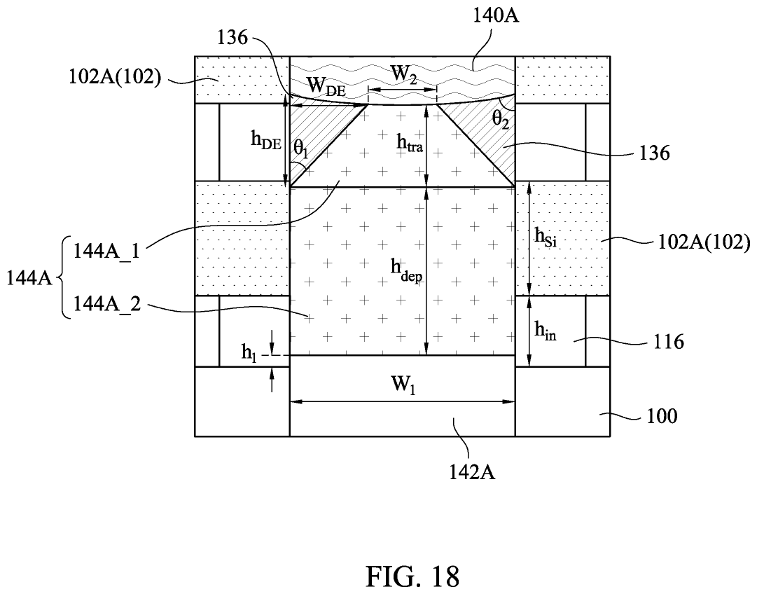

FIG. 18 is an enlarged view of a semiconductor device in accordance with some embodiments of the present disclosure. In greater detail, FIG. 18 is an enlarged view of the first transistor TR1 shown in FIG. 17. It is noted that some elements of FIG. 18 have been described above, and thus relevant details will not be repeated for brevity. In the embodiments of FIG. 18, top surfaces of the dielectric structures 136 are substantially coplanar with the horizontal surface of the epitaxial layer 144A.

With respect to the epitaxial layer 142A, the epitaxial layer 142A has a width W₁, in which the width W₁ is in a range from about 10 nm to about 50 nm in some embodiments. The height difference hi between top surface of the epitaxial layer 142A and top surface of the substrate 100 is in a range from about −10 nm to about 5 nm in some embodiments. That is, the top surface of the epitaxial layer 142A may be higher than or lower than top surface of the substrate 100. The inner spacer 116 has a height hᵢₙ, in which the height hᵢₙ is in a range from about 3 nm to about 15 nm in some embodiments. The semiconductor layer 102 has a height h_{Si}, in which the height h_{Si} is in a range from about 3 nm to about 15 nm in some embodiments.

With respect to the epitaxial layer 144A, the epitaxial layer 144A may include a bottom portion 144A_2 and a top portion 144A_1 over the bottom portion 144A_2. In some embodiments, the bottom portion 144A_2 may include a rectangular cross-sectional profile, and the top portion 144A_1 may include a trapezoidal cross-sectional profile. That is, the width of the top portion 144A_1 may decrease upwardly. The bottom portion 144A_2 has a height h_{dep}, in which the height h_{dep} is in a range from about 3 nm to about 90 nm in some embodiments. The top portion 144A_1 has a height hₜᵣₐ, in which the height hₜᵣₐ is in a range from about 3 nm to about 20 nm in some embodiments. That is, the bottom portion 144A_2 may be thicker than the top portion 144A_1. The bottom portion 144A_2 may also include a width W₁. The horizontal surface of the top portion 144A_1 has a width W₂, in which the width W₂ is in a range from about 1 nm to about 30 nm in some embodiments.

With respect to the dielectric structures 136, each of the dielectric structures 136 may include a triangular cross-sectional profile. The dielectric structure 136 has a height h_{DE}, in which the height h_{DE} is in a range from about 3 nm to about 20 nm in some embodiments. In some embodiments, the height h_{DE} of the dielectric structure 136 may be greater than or equal to the height h_{Si} of the semiconductor layer 102. The dielectric structure 136 has a width W_{DE}, in which the width W_{DE}, the width W2, and the width W1 substantially satisfy W₁>W₂ and W₁=W₂+2W_{DE}. The dielectric structure 136 may include an angle θ1 defined by a vertical sidewall of the dielectric structure 136 and an inclined sidewall of the dielectric structure 136, in which 15°≤θ₁≤75°. The dielectric structure 136 may include an angle θ2 defined by the vertical sidewall of the dielectric structure 136 and a top surface of the dielectric structure 136, in which 30°≤θ₂≤150°.

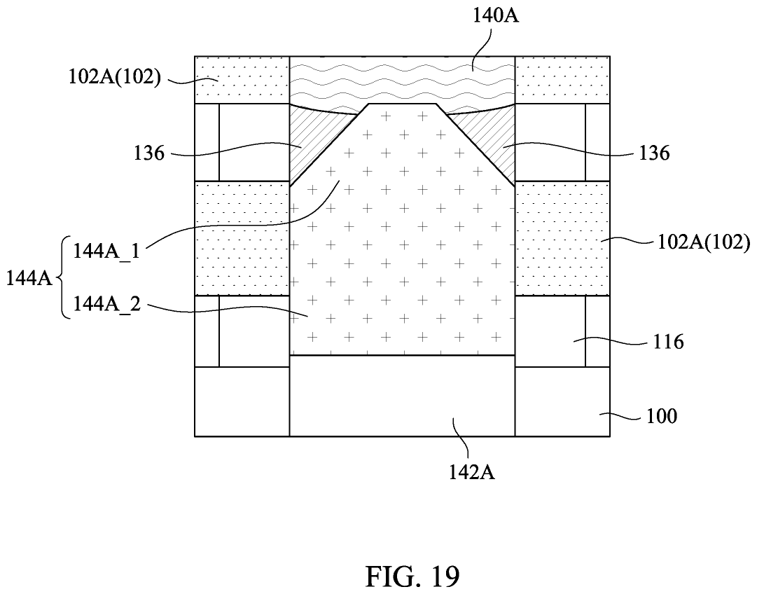

FIG. 19 is an enlarged view of a semiconductor device in accordance with some embodiments of the present disclosure. FIG. 19 is similar to FIG. 18, the difference between FIG. 19 and FIG. 18 is that top surfaces of the dielectric structures 136 are lower than the horizontal surface of the epitaxial layer 144A. As a result, the source/drain epitaxial structures 140A may be in contact and form interfaces with the inclined surfaces of the epitaxial layer 144A.

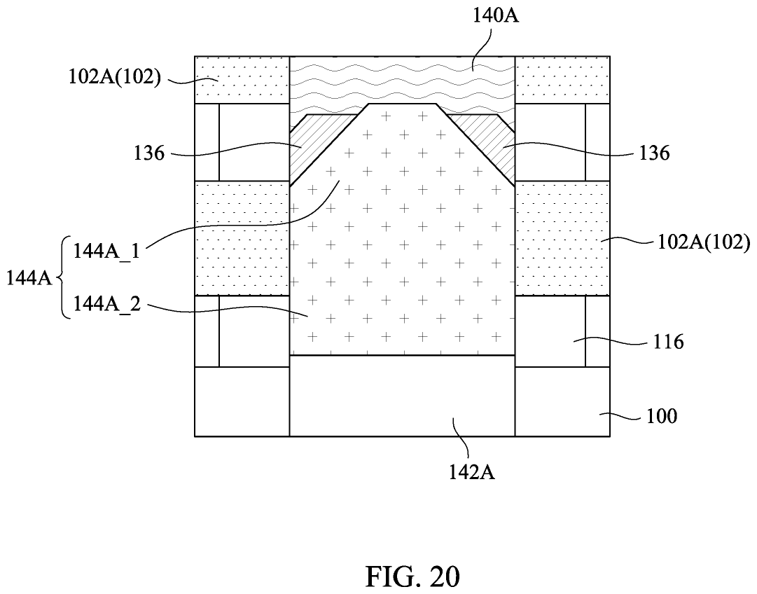

FIG. 20 is an enlarged view of a semiconductor device in accordance with some embodiments of the present disclosure. FIG. 20 is similar to FIG. 18, the difference between FIG. 20 and FIG. 18 is that the dielectric structures 136 may also include trapezoidal cross-sectional profiles.

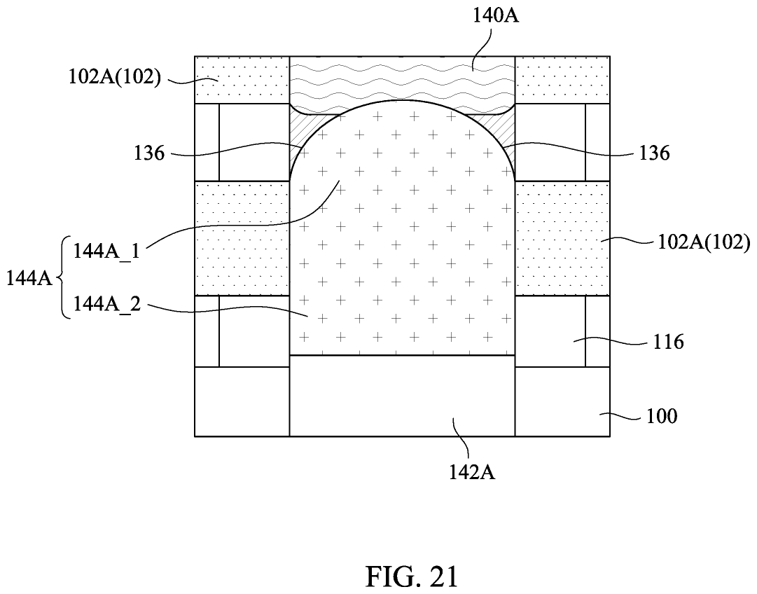

FIG. 21 is an enlarged view of a semiconductor device in accordance with some embodiments of the present disclosure. FIG. 21 is similar to FIG. 18, the difference between FIG. 21 and FIG. 18 is that the top surface of the source/drain epitaxial structures 140A includes a rounded profile. Stated another way, each of the source/drain epitaxial structures 140A may include a convex top surface. In some embodiments, a portion of the convex top surface of the source/drain epitaxial structure 140A may protrude over the respective dielectric structures 136.

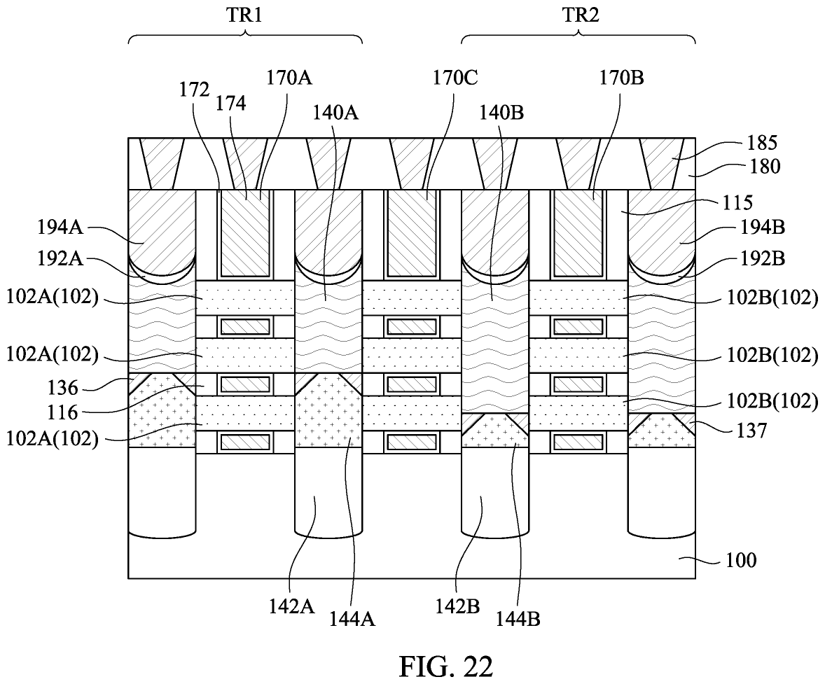

FIG. 22 is a cross-sectional view of a semiconductor device in accordance with some embodiments of the present disclosure. FIG. 22 is similar to FIG. 17, the difference between FIG. 21 and FIG. 18 is that in FIG. 22, there are dielectric structures 137 on opposite sides of each of the epitaxial layers 144B. The material of the dielectric structures 137 is similar to the dielectric structures 136. The structural relationship between the dielectric structures 137 and the respective epitaxial layer 144B is similar to those described with respect to the dielectric structures 136 and the respective epitaxial layer 144A. Moreover, the dielectric structures 137 and the respective epitaxial layer 144B may also include variations similar to those described with respect to FIGS. 18 to 21.

The formation of the structure of FIG. 22 is discussed below. During the etching back process as discussed in FIG. 12, the etching process may lower the top surfaces of the epitaxial layers 144B, such that each of the etched epitaxial layers 144B may include a non-flat top surface profile, such as a trapezoidal top surface profile. Then, the dielectric structures 137 may be formed in a similar way as forming the dielectric structures 136 (see FIGS. 7 and 8). For example, dielectric layers are deposited over the epitaxial layers 144B, and an etching back process is then performed to the dielectric layers, such that remaining portions of the dielectric layers are disposed on opposite sides of each of the epitaxial layers 144B. The remaining portions of the dielectric layer are referred to as the dielectric structures 137.

Because the epitaxial layers 144B are etched back, the following formed source/drain epitaxial structures 140B may be in contact with three semiconductor layers 102B to obtain a hybrid sheet device. The epitaxial layers 144B exposed through the dielectric structures 137 provide additional nucleation sites for the source/drain epitaxial structures 140B. The dielectric structures 137 may also provide electrical isolation between the source/drain epitaxial structures 140B and the substrate 100, and will prevent current leakage from the source/drain epitaxial structures 140B to the substrate 100. With such configuration, the device performance may be improved.

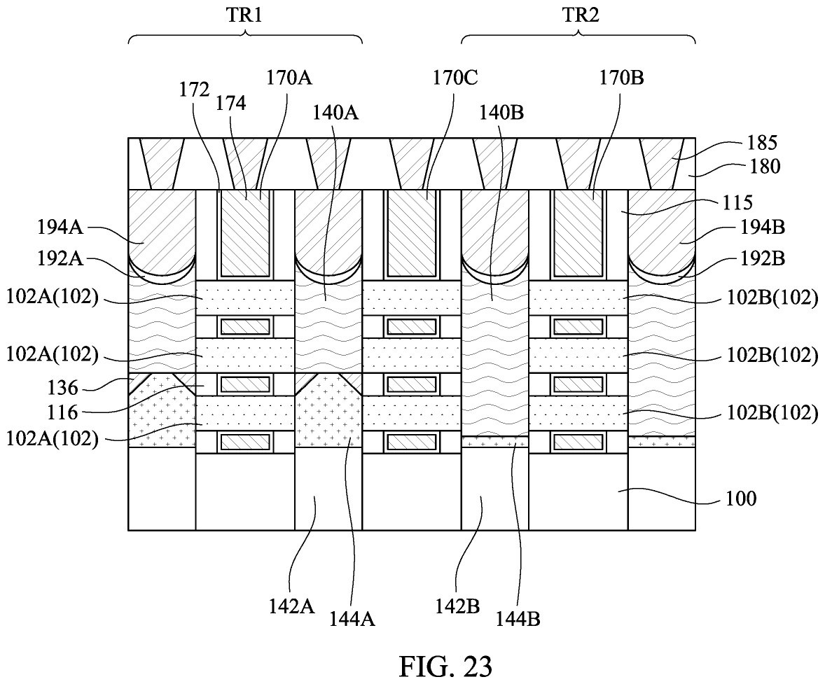

FIGS. 23 to 26 illustrate a method in various stages of forming a semiconductor device in accordance with some embodiments of the present disclosure. In greater detail, FIGS. 23 to 26 describe a method for forming a backside interconnection structure on the structure of FIG. 17. It is noted that the processes as discussed in FIGS. 23 to 26 may be performed by flipping the structure of FIG. 17 by 180 degrees.

Reference is made to FIG. 23. A grinding process is performed on the backside of the structure shown in FIG. 17. In greater detail, the grinding process is performed on the backside of the substrate 100, so as to reduce the thickness of the substrate 100 until the epitaxial layers 142A and 142B are exposed.

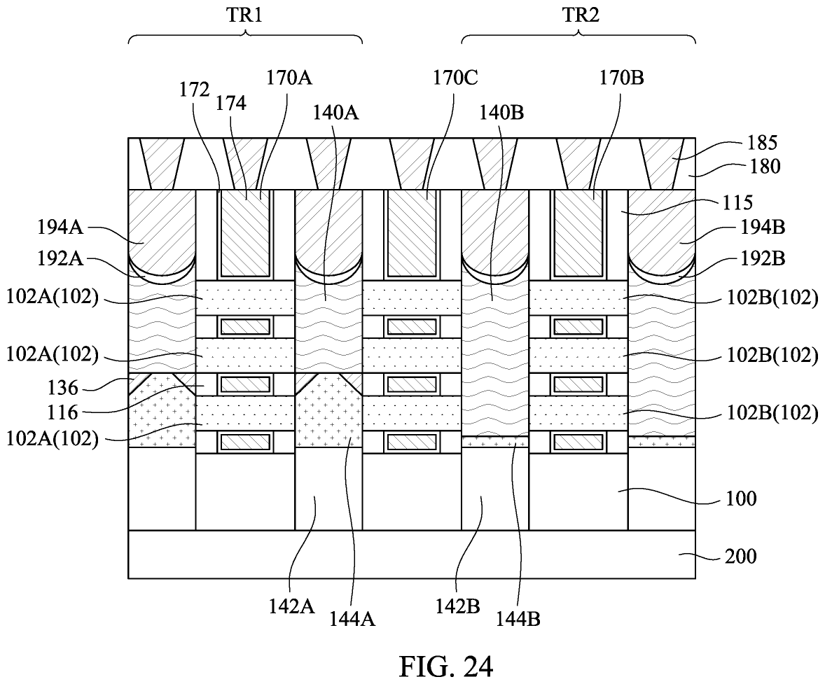

Reference is made to FIG. 24. A backside dielectric layer 200 is formed on the backside of the substrate 100 and covering the exposed epitaxial layers 142A and 142B. In some embodiments, the backside dielectric layer 200 may include silicon oxide, silicon nitride, silicon oxynitride, or the like.

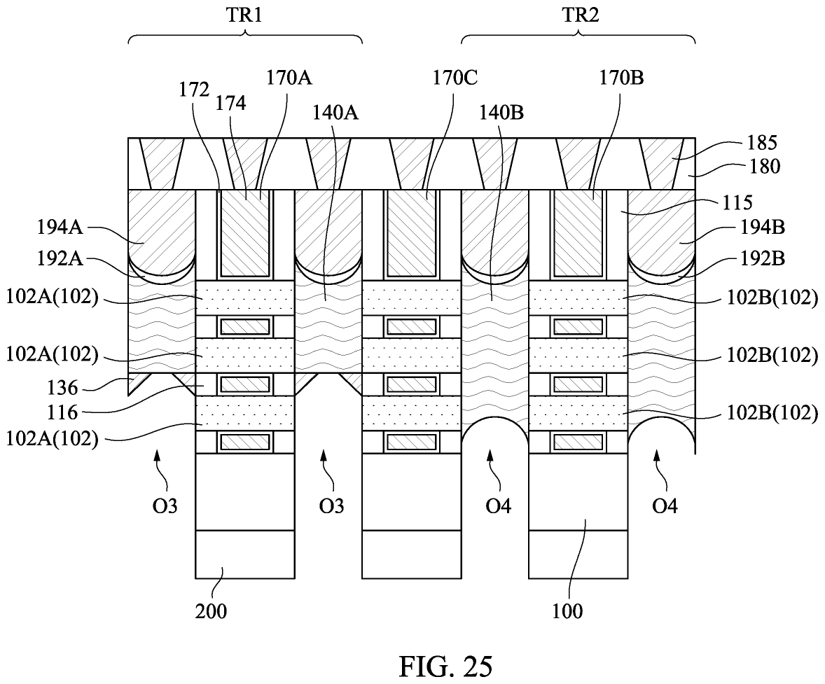

Reference is made to FIG. 25. The backside dielectric layer 200 is then etched, and the epitaxial layers 142A, 144A, 142B, 144B are removed to form openings O3 and O4. In greater detail, the epitaxial layers 142A and 144A are removed to form the openings O3 to expose the source/drain epitaxial structures 140A, and the epitaxial layers 142B and 144B are removed to form the openings O4 to expose the source/drain epitaxial structures 140B. In some embodiments, the dielectric structures 136 may serve as an etch stop layer during the etching process, so as to reduce damage from the source/drain epitaxial structures 140A.

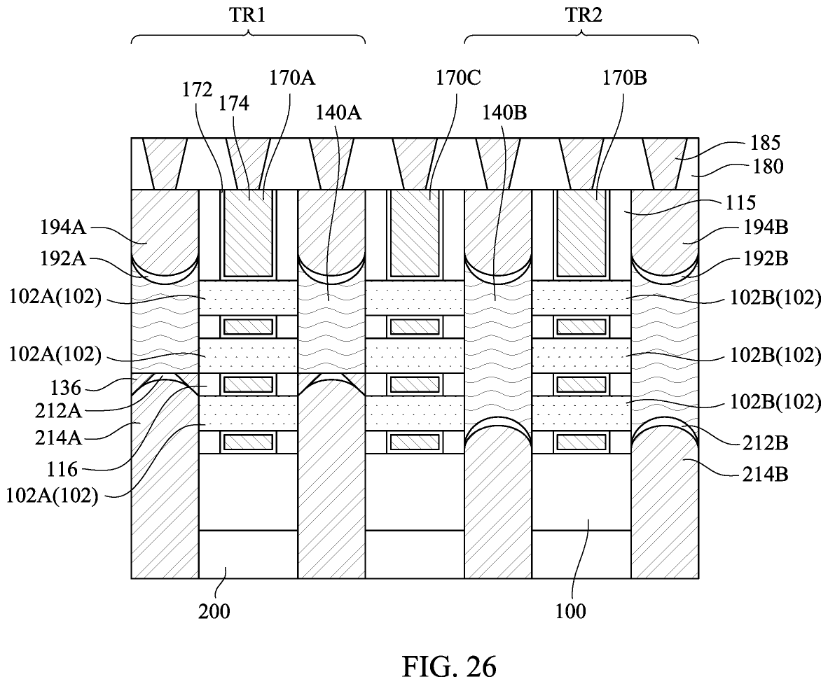

Reference is made to FIG. 26. Silicide layers 212A and 212B are formed in the openings O3 and O4, and on the exposed surfaces of the source/drain epitaxial structures 140A and 140B, respectively. The silicide layers 212A and 212B may include similar material as the silicide layers 192A and 192B. Afterwards, backside vias 214A and 214B are formed in the openings O3 and O4, and over the silicide layers 212A and 212B, respectively, such that the backside vias 214A and 214B are electrically connected to the respective source/drain epitaxial structures 140A and 140B. The backside vias 214A and 214B may include similar material as the source/drain contacts 194A and 194B. In some embodiments, the dielectric structures 136 are disposed on opposite sides of the backside vias 214A and 214B.

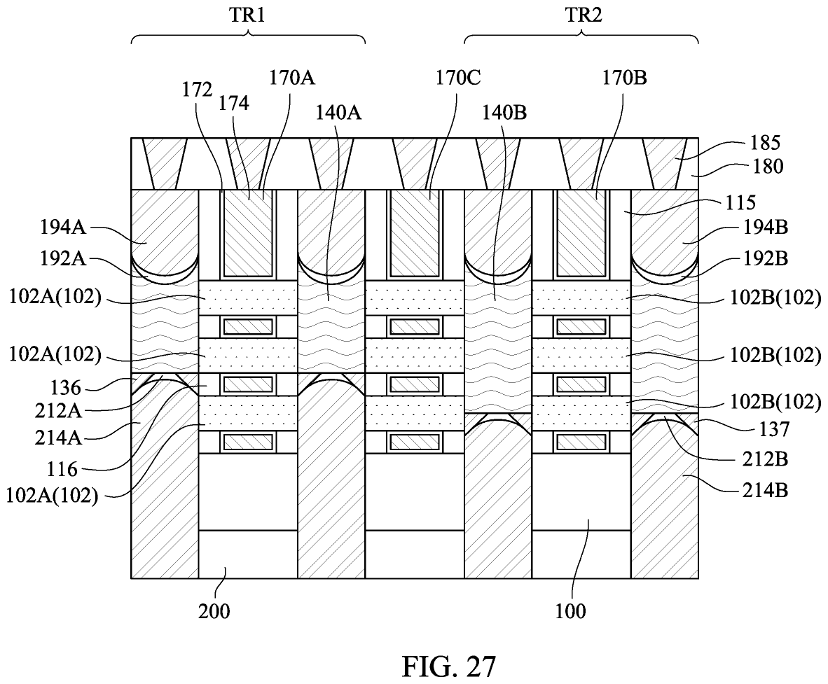

FIG. 27 is a cross-section view of a semiconductor device in accordance with some embodiments of the present disclosure. FIG. 27 is a resulting structure by performing the processes as described in FIGS. 23 to 26 on the structure shown in FIG. 22. That is, during etching the backside dielectric layer 200 and the epitaxial layers 142B and 144B as discussed in FIG. 25, both of the dielectric structures 136 and 137 may serve as an etch stop layer to reduce damage from the source/drain epitaxial structures 140A and 140B.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a hybrid sheet structure. Dielectric structures are formed on opposite ends of un-doped epitaxial capping layers while expose top surface of the un-doped epitaxial capping layers. The exposed epitaxial capping layers may provide additional nucleation sites for the source/drain epitaxial structures, and thus the source/drain epitaxial structures can be formed having a void-free structure. Moreover, the dielectric structures can also provide electrical isolation between the source/drain epitaxial structures and the disabled semiconductor layer, and will prevent current leakage from the source/drain epitaxial structures to the disabled semiconductor layer. Furthermore, the dielectric structures may also serve as an etch stop layer during forming backside interconnection structure to prevent source/drain epitaxial structures from damage. With such configuration, the device performance may be improved.

In some embodiments of the present disclosure, a semiconductor device includes a substrate. Semiconductor layers are stacked one above another over the substrate. A gate structure wraps around each of the semiconductor layers. Epitaxial layers are over the substrate and in contact with opposite ends of a bottommost one of the semiconductor layers. Source/drain epitaxial structures are over and in contact with the epitaxial layers, respectively. Dielectric structures vertically between the epitaxial layers and the respective source/drain epitaxial structures, respectively.

In some embodiments, the epitaxial layers have a trapezoidal top surface profile.

In some embodiments, the dielectric structures have a triangular cross-sectional profile.

In some embodiments, a top surface of each of the epitaxial layers has two inclined portions and a horizontal portion connecting the two inclined portions, and the dielectric structures are in contact with the two inclined portions.

In some embodiments, the horizontal portion of the top surface of each of the epitaxial layers is free of coverage by the respective dielectric structures.

In some embodiments, top surfaces of the dielectric structures are substantially coplanar with the horizontal portion of the top surface of a respective one of the epitaxial layers.

In some embodiments, top surfaces of the dielectric structures are lower than the horizontal portion of the top surface of a respective one of the epitaxial layers.

In some embodiments, the epitaxial layers are made of un-doped silicon germanium.

In some embodiments of the present disclosure, a semiconductor device includes a first transistor and a second transistor. The first transistor includes first semiconductor layers, a first gate structure wrapping around each of the first semiconductor layers, and first source/drain epitaxial structures on opposite sides of the first gate structure, wherein the first source/drain epitaxial structures are separated from at least one of the first semiconductor layers. The second transistor includes second semiconductor layers, a second gate structure wrapping around each of the second semiconductor layers, and second source/drain epitaxial structures on opposite sides of the second gate structure, wherein the second source/drain epitaxial structures are in contact with the second semiconductor layers. First epitaxial layers are below the first source/drain epitaxial structures, respectively, wherein a top surface of one of the first epitaxial layers is in contact with a respective one of the first source/drain epitaxial structures.

In some embodiments, the semiconductor device further includes a first dielectric structure in contact with the top surface of the one of the first epitaxial layers and a bottom surface of the respective one of the first source/drain epitaxial structures.

In some embodiments, the semiconductor device further includes second epitaxial layers below the second source/drain epitaxial structures, respectively. A second dielectric structure is in contact with a top surface of one of the second epitaxial layers and a bottom surface of a respective one of the second source/drain epitaxial structures.

In some embodiments, the first dielectric structure and the second dielectric structure are at different levels.

In some embodiments, the top surface of the one of the first epitaxial layers has a trapezoidal profile.

In some embodiments, the top surface of the one of the first epitaxial layers has two inclined portions and a horizontal portion connecting the two inclined portions, and the horizontal portion of the top surface of the one of the first epitaxial layers is in contact with the respective one of the first source/drain epitaxial structures.

In some embodiments, the two inclined portions of the top surface of the one of the first epitaxial layers are in contact with the respective one of the first source/drain epitaxial structures.

In some embodiments of the present disclosure, a method includes forming first semiconductor layers one above another over a substrate; forming a gate structure over the first semiconductor layers; etching the first semiconductor layers to form a source/drain opening; forming an epitaxial layer in the source/drain opening; forming a dielectric layer covering the epitaxial layer; etching back the dielectric layer until a top surface of the epitaxial layer is exposed; and forming a source/drain epitaxial structure in the source/drain opening and in contact with the top surface of the epitaxial layer.

In some embodiments, portions of the dielectric layer remain on opposite sides of the epitaxial layer after etching back the dielectric layer.

In some embodiments, forming the epitaxial layer is performed such that a sidewall of a bottommost one of the semiconductor layers is covered by the epitaxial layer.

In some embodiments, the epitaxial layer has a trapezoidal top surface profile.

In some embodiments, the source/drain epitaxial structure is in contact with a remaining portion of the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
semiconductor layers stacked one above another over the substrate;
a gate structure wrapping around each of the semiconductor layers;
epitaxial layers over the substrate and in contact with opposite ends of a bottommost one of the semiconductor layers;
source/drain epitaxial structures over and in contact with the epitaxial layers, respectively; and
dielectric structures vertically between the epitaxial layers and the respective source/drain epitaxial structures, respectively.

2. The semiconductor device of claim 1, wherein the epitaxial layers have a trapezoidal top surface profile.

3. The semiconductor device of claim 1, wherein the dielectric structures have a triangular cross-sectional profile.

4. The semiconductor device of claim 1, wherein a top surface of each of the epitaxial layers has two inclined portions and a horizontal portion connecting the two inclined portions, and the dielectric structures are in contact with the two inclined portions.

5. The semiconductor device of claim 4, wherein the horizontal portion of the top surface of each of the epitaxial layers is free of coverage by the respective dielectric structures.

6. The semiconductor device of claim 4, wherein top surfaces of the dielectric structures are substantially coplanar with the horizontal portion of the top surface of a respective one of the epitaxial layers.

7. The semiconductor device of claim 4, wherein top surfaces of the dielectric structures are lower than the horizontal portion of the top surface of a respective one of the epitaxial layers.

8. The semiconductor device of claim 1, wherein the epitaxial layers are made of un-doped silicon germanium.

9. A semiconductor device, comprising:
a first transistor, comprising:
first semiconductor layers;
a first gate structure wrapping around each of the first semiconductor layers; and
first source/drain epitaxial structures on opposite sides of the first gate structure, wherein the first source/drain epitaxial structures are separated from at least one of the first semiconductor layers;
a second transistor, comprising:
second semiconductor layers;
a second gate structure wrapping around each of the second semiconductor layers; and
second source/drain epitaxial structures on opposite sides of the second gate structure, wherein the second source/drain epitaxial structures are in contact with the second semiconductor layers; and
first epitaxial layers below the first source/drain epitaxial structures, respectively, wherein a top surface of one of the first epitaxial layers is in contact with a respective one of the first source/drain epitaxial structures.

10. The semiconductor device of claim 9, further comprising a first dielectric structure in contact with the top surface of the one of the first epitaxial layers and a bottom surface of the respective one of the first source/drain epitaxial structures.

11. The semiconductor device of claim 10, further comprising:
second epitaxial layers below the second source/drain epitaxial structures, respectively; and
a second dielectric structure in contact with a top surface of one of the second epitaxial layers and a bottom surface of a respective one of the second source/drain epitaxial structures.

12. The semiconductor device of claim 11, wherein the first dielectric structure and the second dielectric structure are at different levels.

13. The semiconductor device of claim 9, wherein the top surface of the one of the first epitaxial layers has a trapezoidal profile.

14. The semiconductor device of claim 9, wherein the top surface of the one of the first epitaxial layers has two inclined portions and a horizontal portion connecting the two inclined portions, and the horizontal portion of the top surface of the one of the first epitaxial layers is in contact with the respective one of the first source/drain epitaxial structures.

15. The semiconductor device of claim 14, wherein the two inclined portions of the top surface of the one of the first epitaxial layers are in contact with the respective one of the first source/drain epitaxial structures.

16. A method, comprising:
forming first semiconductor layers one above another over a substrate;
forming a gate structure over the first semiconductor layers;
etching the first semiconductor layers to form a source/drain opening;
forming an epitaxial layer in the source/drain opening;
forming a dielectric layer covering the epitaxial layer;
etching back the dielectric layer until a top surface of the epitaxial layer is exposed; and
forming a source/drain epitaxial structure in the source/drain opening and in contact with the top surface of the epitaxial layer.

17. The method of claim 16, wherein portions of the dielectric layer remain on opposite sides of the epitaxial layer after etching back the dielectric layer.

18. The method of claim 16, wherein forming the epitaxial layer is performed such that a sidewall of a bottommost one of the first semiconductor layers is covered by the epitaxial layer.

19. The method of claim 16, wherein the epitaxial layer has a trapezoidal top surface profile.

20. The method of claim 16, wherein the source/drain epitaxial structure is in contact with a remaining portion of the dielectric layer.
